(19) United States
(12) Patent Application Publication
(10) Pub. No.: US 2026/0156794 A1
(43) Pub. Date: Jun. 4, 2026

(54) Vertically Stacked 8T Complementary FET SRAM

(71) Applicant: International Business Machines Corporation, Armonk, NY (US)

(72) Inventors: Rajiv Joshi, Yorktown Heights, NY (US); Ruilong Xie, Niskayuna, NY (US); Carl Radens, LaGrangeville, NY (US); Dureseti Chidambarrao, Weston, CT (US)

(21) Appl. No.: 18/964,972

(22) Filed: Dec. 2, 2024

(51) Int. Cl. H10B 10/00; G11C 11/412; G11C 11/419

(52) U.S. Cl. CPC H10B 10/12; G11C 11/412; G11C 11/419

(57) ABSTRACT

A static random access memory (SRAM) integrated circuit comprises a plurality of PMOS and NMOS transistors connected to a first storage node and a second storage node. The PMOS transistors are fabricated in an upper layer of the integrated circuit and the NMOS transistors are fabricated in a lower layer of the integrated circuit. A voltage supply rail, a write word line, a read bit line and a read word line are formed in the upper layer. A ground rail, a write bit line and a complementary write bit line are formed in the lower layer.

### BACKGROUND

This disclosure relates generally to semiconductor integrated circuits (ICs), and more specifically to 8T complementary FET SRAMs.

Static Random Access Memory (SRAM) is a volatile memory that retains data bits as long as power is supplied. Unlike Dynamic Random Access Memory (DRAM), SRAM doesn't need to be periodically refreshed, which makes it faster and more reliable for certain applications.

SRAMs are widely used in computing systems, particularly as cache memory within processors and in various high-speed applications. Conventional SRAM cells, generally known as 6T SRAM, employ six transistors arranged in a bistable flip-flop configuration to store a single bit of data. Traditional 6T architecture has several disadvantages including its vulnerability to instability and noise.

### SUMMARY

According to illustrative embodiments, a static random access memory (SRAM) circuit comprises a plurality of PMOS and NMOS transistors connected to a first and a second storage node. A first PMOS transistor has a source connected to a voltage supply, a drain connected to the first storage node and a gate connected to the second storage node. A first NMOS transistor has a drain connected to the first storage node, a source connected to a reference potential and a gate connected to the second storage node. A second PMOS transistor has a source connected to the voltage supply, a drain connected to the second storage node and a gate connected to the first storage node. A second NMOS transistor has a drain connected to the second storage node, a source connected to the reference potential and a gate connected to the first storage node. A first pass-gate transistor has a first terminal connected to the first storage node, a second terminal connected to a write bit line and a gate connected to a write word line. A second pass-gate transistor has a first terminal connected to the second storage node, a second terminal connected to a complementary write bit line and a gate connected to the write word line. A third NMOS transistor has a drain connected to a read bit line, a gate connected to a read word line and has a source. A third PMOS transistor has a source connected to the source of the NMOS transistor, a gate connected to the first storage node and a drain connected to a reference potential.

In the illustrative embodiments, the first storage node stores a binary value that is complementary to the binary value stored by the second storage node.

In the illustrative embodiments, in a write operation, the write word line is driven high, causing the first pass-gate transistor and the second pass-gate transistor to turn ON.

In the illustrative embodiments, in a write operation, the write word line is driven high, causing the write bit line to be coupled to the first storage node and the complementary write bit line to be coupled to the second storage node.

In the illustrative embodiments, in a read operation, the read word line is driven high, causing the third NMOS transistor to turn ON.

In the illustrative embodiments, the third PMOS transistor is turned ON if the binary value stored at the first storage node is 0, and the third PMOS transistor is turned OFF if the binary value stored at the first storage node is 1.

In the illustrative embodiments, an SRAM integrated circuit comprises an upper layer and a lower layer separated by a dielectric layer. The upper layer includes a plurality of PMOS transistors, a voltage supply rail, a write word line, a read bit line and a read word line. The lower layer includes a plurality of NMOS transistors, a ground rail, a write bit line and a complementary write bit line. The PMOS transistors are vertically stacked over the NMOS transistors. The write word line contact extends from the upper layer into the lower layer to establish contact with a gate of one of the NMOS transistors in the lower layer.

In the illustrative embodiments, the plurality of PMOS transistors include first, second and third PMOS transistors, and the plurality of NMOS transistors include first, second, third, fourth and fifth NMOS transistors.

In the illustrative embodiments, the first NMOS and PMOS transistors are connected to form a first inverter, and the second NMOS and PMOS transistors are connected to form a second inverter. The first and second inverters are cross-coupled via frontside and backside cross-connects.

In the illustrative embodiments, the third and fourth NMOS transistors are pass-gate transistors.

In the illustrative embodiments, an SRAM circuit comprises a first storage node and a second storage node. A first inverter and a second inverter are cross-coupled at the first and second storage nodes. A first pass gate transistor has a first terminal connected to the first storage node, a second terminal connected to a write bit line and a gate connected to a write word line. A second pass gate transistor has a first terminal connected to the second storage node, a second terminal connected to a complementary write bit line and a gate connected to the write word line. A read circuit has a first terminal connected to a read bit line, a second terminal connected to the first storage node, a third terminal connected to a read word line and a fourth terminal connected to a reference potential.

In the illustrative embodiments, the first inverter comprises a first PMOS transistor which has a source connected to a voltage supply, a drain connected to the first storage node and a gate connected to the second storage node. The first inverter comprises a first NMOS transistor which has a drain connected to the first storage node, a source connected to the reference potential and a gate connected to the second storage node.

In the illustrative embodiments, the second inverter comprises a second PMOS transistor which has a source connected to a voltage supply, a drain connected to the second storage node and a gate connected to the first storage node. The second inverter comprises a second NMOS transistor which has a drain connected to the second storage node, a source connected to the reference potential and a gate connected to the first storage node.

In the illustrative embodiments, the read circuit comprises a third NMOS transistor which has a drain connected to a read bit line, a gate connected to a read word line and having a source, and has a second PMOS transistor which has a source connected to the source of the first NMOS transistor, a gate connected to the first storage node and a drain connected to the reference potential.

In the illustrative embodiments, the first storage node holds a binary value that is complementary to the binary value held by the second storage node.

In the illustrative embodiments, in a write operation, the write word line is driven high, causing the first pass gate transistor and the second pass gate transistor to turn ON.

In the illustrative embodiments, an SRAM integrated circuit comprises an upper layer and a lower layer separated by a dielectric layer. A first PMOS transistor, a second PMOS transistor and a third PMOS transistor are formed in the upper layer. A voltage supply rail, a write word line, a read bit line and a read word line are formed in the upper layer. A first NMOS transistor, a second NMOS transistor, a third NMOS transistor, a fourth NMOS transistor and a fifth NMOS transistor are formed in the lower layer. The PMOS transistors are vertically stacked over the NMOS transistors. A ground rail, a write bit line and a complementary write bit line are formed in the lower layer. The write word line contact extends from the upper layer into the lower layer to establish contact with a gate of the fifth NMOS transistor in the lower layer. The first NMOS and PMOS transistors are connected to form a first inverter, and the second NMOS and PMOS transistors are connected to form a second inverter.

In the illustrative embodiments, the first and second inverters are cross-coupled via frontside and backside cross-connects.

In the illustrative embodiments, the SRAM integrated circuit further comprises a frontside interconnect electrically connected to the voltage supply rail, the write word line, the read bit line and the read word line.

In the illustrative embodiments, the SRAM integrated circuit further comprises a backside interconnect electrically connected to the ground rail, the write bit line and the complementary write bit line.

In the illustrative embodiments, the SRAM integrated circuit further comprises a single diffusion block isolating active regions of the SRAM.

In the illustrative embodiments, in a write operation, the write word line is driven high, causing the write bit line to be coupled to the first storage node and the complementary write bit line to be coupled to the second storage node.

In the illustrative embodiments, in a read operation, the read word line is driven high, causing the third NMOS transistor to turn ON.

### BRIEF DESCRIPTION OF THE DRAWINGS

The novel features believed characteristic of the illustrative embodiments

are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a schematic of an SRAM in accordance with an illustrative embodiment;

FIG. 2 illustrates a layout (top view) of an SRAM cell in accordance with an illustrative embodiment;

FIGS. 3A, 3B, 3C, illustrate cross-section views of the SRAM (as shown in FIG. 2) after a front end of line (FEOL) process;

FIGS. 4A and 4B illustrate cross-section views of the SRAM after formation of contact trenches;

FIGS. 5A and 5B illustrate cross-section views of the SRAM after contact trenches are filled with metal;

FIG. 6A illustrates a layout (top view) of the SRAM after a middle of line (MOL) process;

FIGS. 6B, 6C and 6D illustrate cross-section views of the SRAM after the MOL process;

FIGS. 7A and 7B illustrate cross-section views of the SRAM after a back end of line (BEOL) process;

FIGS. 8A and 8B illustrate cross-section views of the SRAM after removal of a substrate;

FIGS. 9A and 9B illustrate cross-section views of the SRAM after forming backside connectivity;

FIG. 10 illustrates a schematic of an SRAM in accordance with another illustrative embodiment; and

FIG. 11 illustrates a schematic of an SRAM in accordance with another illustrative embodiment.

### DETAILED DESCRIPTION

A static random access memory (SRAM) circuit comprises a plurality of PMOS and NMOS transistors connected to a first and a second storage node. A first PMOS transistor has a source connected to a voltage supply, a drain connected to the first storage node and a gate connected to the second storage node. A first NMOS transistor has a drain connected to the first storage node, a source connected to a reference potential and a gate connected to the second storage node. A second PMOS transistor has a source connected to the voltage supply, a drain connected to the second storage node and a gate connected to the first storage node. A second NMOS transistor has a drain connected to the second storage node, a source connected to the reference potential and a gate connected to the first storage node. A first pass-gate transistor has a first terminal connected to the first storage node, a second terminal connected to a write bit line and a gate connected to a write word line. A second pass-gate transistor has a first terminal connected to the second storage node, a second terminal connected to a complementary write bit line and a gate connected to the write word line. A third NMOS transistor has a drain connected to a read bit line, a gate connected to a read word line and has a source. A third PMOS transistor has a source connected to the source of the source NMOS transistor, a gate connected to the first storage node and a drain connected to a reference potential. As a result, the illustrative embodiments provide a technical effect of isolating read operations from the storage nodes.

In the illustrative embodiments, the first storage node stores a binary value that is complementary to the binary value stored by the second storage node. As a result, the illustrative embodiments provide a technical effect of noise immunity and stability by providing differential outputs.

In the illustrative embodiments, in a write operation, the write word line is driven high, causing the first pass-gate transistor and the second pass-gate transistor to turn ON. As a result, the illustrative embodiments provide a technical effect of facilitating connections to the first and second storage nodes during a write operation.

In the illustrative embodiments, in a write operation, the write word line is driven high, causing the write bit line to be coupled to the first storage node and the complementary write bit line to be coupled to the second storage node. As a result, the illustrative embodiments provide a technical effect of connecting the write bit lines to the storage nodes to facilitate a write operation.

In the illustrative embodiments, in a read operation, the read word line is driven high, causing the third NMOS transistor to turn ON. As a result, the illustrative embodiments provide a technical effect of coupling the third NMOS transistor to the write bit line.

In the illustrative embodiments, the third PMOS transistor is turned ON if the binary value stored at the first storage node is 0, and the third PMOS transistor is turned OFF if the binary value stored at the first storage node is 1. As a result, the illustrative embodiments provide a technical effect of isolating a read operation from a write operation.

In the illustrative embodiments, an SRAM integrated circuit comprises an upper layer and a lower layer separated by a dielectric layer. The upper layer includes a plurality of PMOS transistors, a voltage supply rail, a write word line, a read bit line and a read word line. The lower layer includes a plurality of NMOS transistors, a ground rail, a write bit line and a complementary write bit line. The PMOS transistors are vertically stacked over the NMOS transistors. A write word line contact extends from the upper layer into the lower layer to establish contact with a gate of one of the NMOS transistors in the lower layer. As a result, the illustrative embodiments provide a technical effect of forming a vertically stacked SRAM cell which reduces the overall cell footprint, allowing for higher memory density.

In the illustrative embodiments, the plurality of PMOS transistors include first, second and third PMOS transistors, and the plurality of NMOS transistors include first, second, third, fourth and fifth NMOS transistors. As a result, the illustrative embodiments provide a technical effect of allowing the PMOS transistors to be stacked vertically over the NMOS transistors.

In the illustrative embodiments, the first NMOS and PMOS transistors are connected to form a first inverter, and the second NMOS and PMOS transistors are connected to form a second inverter. The first and second inverters are cross-coupled via frontside and backside cross-connects. As a result, the illustrative embodiments provide a technical effect of storing data in a bi-stable flip-flop.

In the illustrative embodiments, the third and fourth NMOS transistors are pass-gate transistors. As a result, the illustrative embodiments provide a technical effect of forming the pass-gate transistors in the lower layer.

In another illustrative embodiments, an SRAM circuit comprises a first storage node and a second storage node. A first inverter and a second inverter are cross-coupled at the first and second storage nodes. A first pass gate transistor has a first terminal connected to the first storage node, a second terminal connected to a write bit line and a gate connected to a write word line. A second pass gate transistor has a first terminal connected to the second storage node, a second terminal connected to a complementary write bit line and a gate connected to the write word line. A read circuit has a first terminal connected to a read bit line, a second terminal connected to the first storage node, a third terminal connected to a read word line and a fourth terminal connected to a reference potential. As a result, the illustrative embodiments provide a technical effect of isolating read operations from the storage nodes.

In the illustrative embodiments, the first inverter comprises a first PMOS transistor which has a source connected to a voltage supply, a drain connected to the first storage node and a gate connected to the second storage node. The first inverter comprises a first NMOS transistor which has a drain connected to the first storage node, a source connected to the reference potential and a gate connected to the second storage node. As a result, the illustrative embodiments provide a technical effect of storing data in a bi-stable flip-flop.

In the illustrative embodiments, the second inverter comprises a second PMOS transistor which has a source connected to a voltage supply, a drain connected to the second storage node and a gate connected to the first storage node. The second inverter comprises a second NMOS transistor which has a drain connected to the second storage node, a source connected to the reference potential and a gate connected to the first storage node. As a result, the illustrative embodiments provide a technical effect of storing data in a bi-stable flip-flop.

In the illustrative embodiments, the read circuit comprises a third NMOS transistor which has a drain connected to a read bit line, a gate connected to a read word line and having a source, and has a second PMOS transistor which has a source connected to the source of the first NMOS transistor, a gate connected to the first storage node and a drain connected to the reference potential. As a result, the illustrative embodiments provide a technical effect of isolating a read operation from a write operation.

In the illustrative embodiments, the first storage node holds a binary value that is complementary to the binary value held by the second storage node. As a result, the illustrative embodiments provide a technical effect of noise immunity and stability by providing differential outputs.

In the illustrative embodiments, in a write operation, the write word line is driven high, causing the first pass gate transistor and the second pass gate transistor to turn ON. As a result, the illustrative embodiments provide a technical effect of connecting the write bit lines to the storage nodes to facilitate a write operation.

In the illustrative embodiments, an SRAM integrated circuit comprises an upper layer and a lower layer separated by a dielectric layer. A first PMOS transistor, a second PMOS transistor and a third PMOS transistor are formed in the upper layer. A voltage supply rail, a write word line, a read bit line and a read word line are formed in the upper layer. A first NMOS transistor, a second NMOS transistor, a third NMOS transistor, a fourth NMOS transistor and a fifth NMOS transistor are formed in the lower layer. The PMOS transistors are vertically stacked over the NMOS transistors. A ground rail, a write bit line and a complementary write bit line are formed in the lower layer. A write word line contact extends from the upper layer into the lower layer to establish contact with a gate of the fifth NMOS transistor in the lower layer. The first NMOS and PMOS transistors are connected to form a first inverter, and the second NMOS and PMOS transistors are connected to form a second inverter. As a result, the illustrative embodiments provide a technical effect of forming a vertically stacked SRAM cell which reduces the overall cell footprint, allowing for higher memory density.

In the illustrative embodiments, the first and second inverters are cross-coupled via frontside and backside cross-connects. As a result, the illustrative embodiments provide a technical effect of forming a bi-stable flip-flop.

In the illustrative embodiments, the SRAM integrated circuit further comprises a frontside interconnect electrically connected to the voltage supply rail, the write word line, the read bit line and the read word line. As a result, the illustrative embodiments provide a technical effect of reducing the overall cell footprint, allowing for higher memory density.

In the illustrative embodiments, the SRAM integrated circuit further comprises a backside interconnect electrically connected to the ground rail, the write bit line and the complementary write bit line. As a result, the illustrative embodiments provide a technical effect of reducing the overall cell footprint, allowing for higher memory density.

In the illustrative embodiments, the SRAM integrated circuit further comprises a single diffusion block isolating active regions of the SRAM. As a result, the illustrative embodiments provide a technical effect of isolating active devices to reduce parasitic effects in the SRAM.

In the illustrative embodiments, in a write operation, the write word line is driven high, causing the write bit line to be coupled to the first storage node and the complementary write bit line to be coupled to the second storage node. As a result, the illustrative embodiments provide a technical effect of connecting the write bit lines to the storage nodes to facilitate a write operation.

In the illustrative embodiment, in a read operation, the read word line is driven high, causing the third NMOS transistor to turn ON. As a result, the illustrative embodiments provide a technical effect of facilitating a read operation.

Various aspects of the present disclosure are described by narrative text, schematics, layouts and cross-section views.

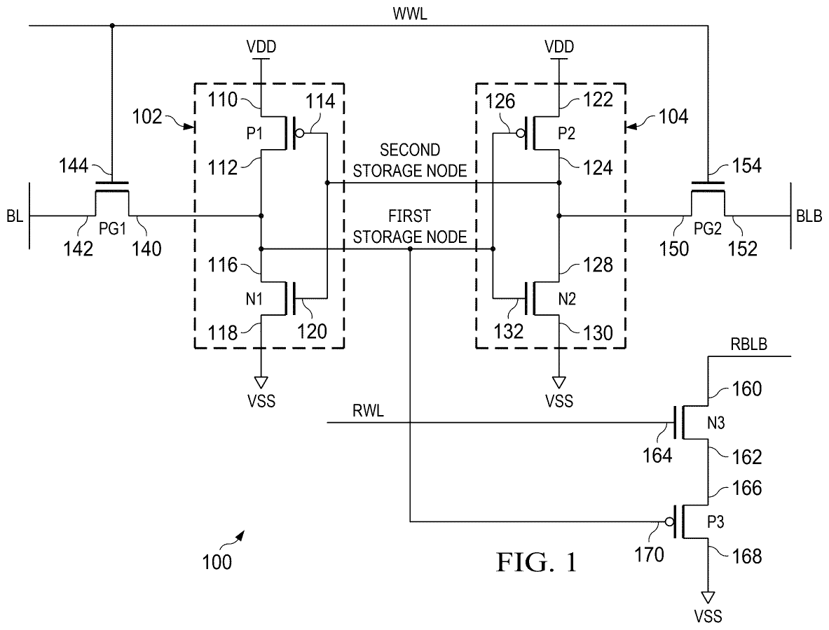

FIG. 1 illustrates a schematic of 8T SRAM 100 in accordance with an illustrative embodiment. SRAM 100 includes 2 cross-coupled inverters 102 and 104 that hold the data in a bistable flip-flop. Inverters 102 and 104 are implemented using Complementary Metal Oxide Semiconductor (CMOS) technology that includes both NMOS and PMOS transistors.

Inverter 102 includes PMOS transistor P1 and NMOS transistor N1. Transistor P1 has source 110 connected to voltage supply VDD (e.g., voltage rail) and has drain 112 and gate 114. Transistor N1 has drain 116 connected to drain 112 of P1 and has source 118 connected to reference potential VSS (e.g., ground) and has gate 120. Drains 112/116 are also referred to as the first storage node of SRAM 100.

Inverter 104 includes PMOS transistor P2 and NMOS transistor N2. Transistor P2 has source 122 connected to voltage supply VDD and has drain 124 and gate 126. Transistor N2 has drain 128 connected to drain 124 of P2 and has source 130 connected to reference potential VSS (e.g., ground) and has gate 132.

Inverters 102 and 104 are cross-connected by connecting drains 112/116 to gates 126/132 and by connecting drains 124/128 to gates 114/120. The node at which drains 112/116 and gates 126/132 are interconnected is referred to as the first storage node. The node at which drains 124/128 and gates 114/120 are interconnected is referred to as the second storage node.

SRAM 100 includes pass-gate transistor PG1 which has first terminal 140 connected to drains 112/116, second terminal 142 coupled to write bit line (BL) and gate 144 coupled to write word line (WWL). SRAM 100 includes pass-gate transistor PG2 which has first terminal 150 connected to drains 124/128, second terminal 152 coupled to write bit line bar (BLB) (also referred to as complementary BL) and gate 154 coupled to WWL.

In the illustrative embodiment, BL carries the signal that represents either binary value 0 or 1 which is stored in SRAM 100. BLB carries the complementary signal to BL. This differential line (BLB) is the inverse of the signal present on BL, providing noise immunity and stability. WWL controls access to SRAM 100 during write operations. WWL enables or disables the connection between the bit lines (e.g., BL and BLB) and the first and second storage nodes of SRAM 100, which determines whether new data can be written into the SRAM. When WWL is asserted (e.g., driven high), transistors PG1 and PG2 are turned ON. Transistors PG1 and PG2 connect the first and second storage nodes (which store 0 or 1) to the write bit lines (BL and BLB).

SRAM 100 includes NMOS transistor N3 which has drain 160 connected to read bit line (RBLB), source 162, and has gate 164 connected to read word line (RWL). SRAM 100 includes PMOS transistor P3 which has source 166 connected to source 162 of N1, drain 168 connected to reference potential VSS (e.g., ground rail) and has gate 170 connected to gates 126 and 132.

During a write operation, WWL is asserted (e.g., driven HIGH) which turns ON pass-gate transistors PG1 and PG2, thus coupling drains 112/116 and gates 126/132 to write bit line BL. To write logic 1, BL is set HIGH, which causes transistor P2 to turn OFF but transistor N2 to turn ON. Thus, drains 124/128 and gates 114/120 (e.g., second storage node) are pulled to ground. As a result, transistor P1 is turned ON but transistor N1 is turned OFF, resulting in VDD to be coupled to drains 112/116. Thus, drains 112/116 (e.g., first storage node) are held at logic 1. Also, because transistor N2 is turned ON, drains 124/128 (e.g., second storage node) are held at logic 0.

To write logic 0, BL is driven LOW, which causes transistor P2 to turn ON but transistor N2 to turn OF. Thus, drains 124/128 and gates 114/120 are pulled high to VDD. As a result, transistor P1 is turned OFF but transistor N1 is turned ON, which causes VSS to be coupled to drains 112 and 116. Thus, drains 112/116 (e.g., first storage node) are held at logic 0. Also, because transistor P2 is turned ON, drains 124/128 (e.g., second storage node) are held at logic 1. Inverter pair 102 and 104 holds the data in a bistable flip-flop because the logic state of drains 112/116 (e.g., first storage node) is complementary to the logic state of drains 124/128 (e.g., second storage node).

During a read operation, RWL is asserted (e.g., driven HIGH). Thus, transistor N3 is turned ON, which causes read local bit line (RBLB) to be coupled to source 162. If the logic state at drains 112/116 is logic 1, transistor P3 is turned OFF, causing drain 166 and source 162 to be held HIGH (e.g., logic 1). If logic state at drains 112/116 is logic 0, transistor P3 is turned ON, causing drain 166 to be pulled to VSS (e.g., ground).

In the illustrative embodiment, transistors N3 and P3 isolate the read operation from the storage node. This separation ensures that the read process does not interfere with the stored data. By isolating the read path, SRAM 100 prevents read disturb issues, making the read operation more stable and reliable, particularly at low voltages. Also, because RBLB is independent, read access can be faster as SRAM 100 is not slowed down by the effect of read disturb or weak storage nodes.

In the illustrative embodiment, the additional two transistors consist of NMOS transistor N3 and PMOS transistor P3, rather than the conventional 8T SRAM configuration, which typically uses two additional NMOS transistors for a dedicated read path. By using one NMOS N3 and one PMOS P3 transistor, these transistors can be stacked vertically, creating a stacked SRAM structure that occupies less area on an integrated circuit. This stacked arrangement reduces the overall cell footprint, allowing for higher memory density and making the design more area-efficient compared to conventional 8T SRAM. The reduction in area is advantageous in advanced technology nodes, where minimizing circuit size is essential for cost-effective and high-density memory applications.

In an illustrative embodiment, SRAM 100 is fabricated as a semiconductor integrated circuit (IC), where PMOS transistors are formed in an upper layer and NMOS transistors are fabricated in a lower layer of the IC. This stacked arrangement significantly reduces cell footprint, saving valuable chip area and enabling higher memory density. By separating the NMOS and PMOS transistors into distinct layers, this stacked structure improves routing efficiency and minimizes wiring congestion, as the transistors are separated vertically rather than spread across a single plane. Also, this layered approach supports optimized transistor performance, as PMOS and NMOS transistors can be individually tuned and processed in their respective layers, improving switching speed and reducing leakage.

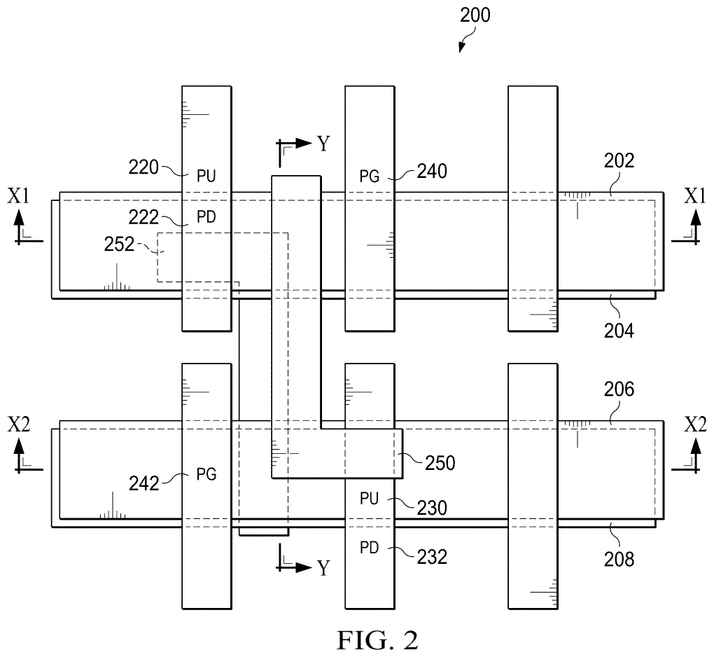

FIG. 2 illustrates top view 200 (layout) of an SRAM cell fabricated as an integrated circuit (IC) in accordance with an illustrative embodiment. In view 200, the SRAM is shown at a point in fabrication after a front end of line (FEOL) process. The FEOL process in semiconductor fabrication involves forming active components of the SRAM on the frontside of a silicon wafer. The FEOL process creates individual transistors and associated elements that make up the SRAM cell. This phase is completed before middle of line (MOL) and back end of line (BEOL) processes, which handle contacts, interconnects and routing.

In view 200, X1 cut runs laterally across active regions 202 and 204, which are formed in upper and lower layers, respectively, of the IC. X2 cut runs laterally across active regions 206 and 208 which are formed in upper and lower layers, respectively, of the IC. Additionally, Y1 cut runs transversely across X1 and X2 cuts.

In the illustrative embodiment, pull-up transistor 220 is fabricated in active region 202 in the upper layer and pull-down transistor 222 is fabricated in active region 204 in the lower layer. Pull-up transistor 220 and pull-down transistor 222 are stacked vertically. Pull-up transistor 220 can be PMOS transistor P1 (as shown in FIG. 1) and pull-down transistor 222 can be NMOS transistor N1 (as shown in FIG. 1). Transistors P1 and N1 are connected to form inverter 102 (as shown in FIG. 1).

Also, as shown in FIG. 2, pull-up transistor 230 is fabricated in active region 206 in the upper layer and pull-down transistor 232 is fabricated in active region 208 in the lower layer. Pull-up transistor 230 and pull-down transistor 232 are stacked vertically. Pull-up transistor 230 can be PMOS transistor P2 (as shown in FIG. 1) and pull-down transistor 232 can be NMOS transistor N2 (as shown in FIG. 1). Transistors P2 and N2 are connected to form inverter 104 (as shown in FIG. 1).

In the illustrative embodiment, pass gate transistors 240 and 242 are formed in the lower layer. Pass-gate transistor 240 may correspond to pass-gate transistor PG1 (as shown in FIG. 1) and pass-gate transistor 242 may correspond to pass-gate transistor PG2 (as shown in FIG. 1). Frontside cross-connect 250 and backside cross-connect 252 cross-connect the two inverters (e.g., inverters 102 and 104 shown in FIG. 1).

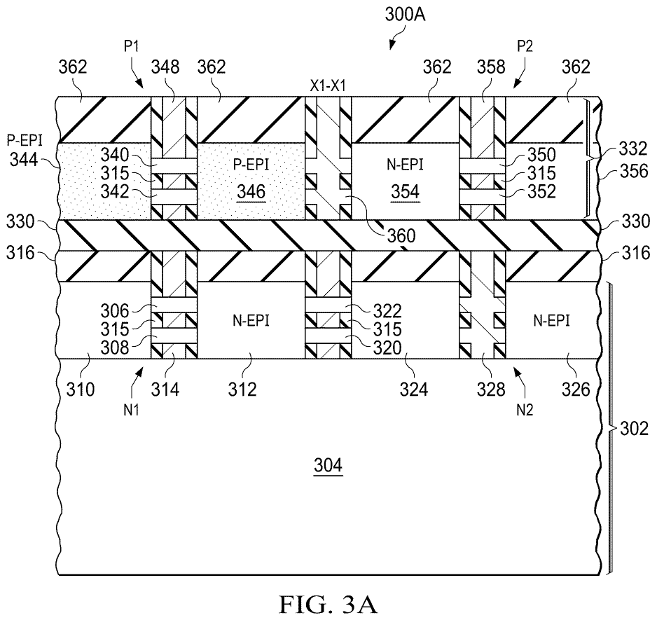

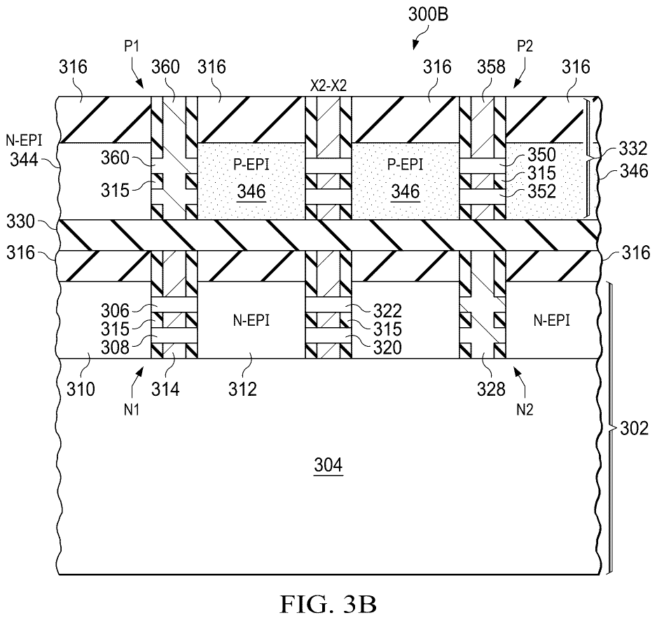

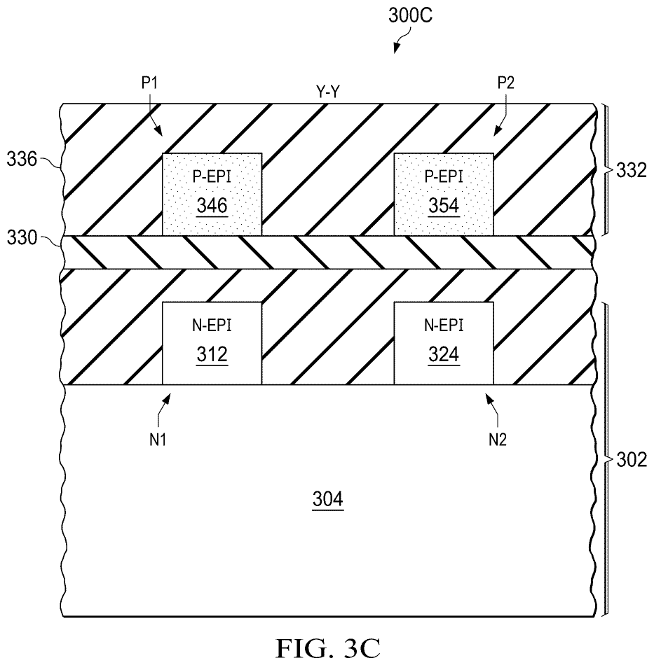

FIG. 3A illustrates cross-section view 300A of the SRAM (e.g., SRAM 100, 200) along X1 cut (as shown in FIG. 2). In this view, the SRAM is shown at a point in fabrication after the FEOL process.

The process begins by forming NMOS transistors N1 and N2 in lower layer. Transistor N1 includes channels 306 and 308, which are made of silicon (e.g., p-type silicon), which is normally non-conductive (does not allow electrons to flow freely) until a positive voltage is applied to the gate. The channels are the pathways that allow electrons to flow from a source to a drain. Transistor N1 includes epitaxial (Epi) regions 310 and 312, which are formed in the substrate. Epitaxial regions 310 and 312 are layers of silicon or other materials that are grown on silicon substrate 304 to create a high-quality crystalline layer. Epitaxial regions 310 and 312 are used to form the source and drain regions of transistor N1. The epitaxial regions are heavily doped to create entry (source) and exit (drain) points for electrons in the channels.

Metal gate 314 is formed across channels 306 and 308. In the illustrative embodiment, metal gate 314 is a high-k metal gate which improves gate control and reduces leakage current. A high-k dielectric material such as hafnium oxide (HfO₂) is deposited across channels 306 and 308 and metals such as titanium nitride (TiN) or tungsten (W) are used to form a gate electrode. The high-k dielectric material separates the gate electrode from channels 306 and 308.

Spacer 315 (e.g., insulating material) is deposited along sidewalls of metal gate 314 and epitaxial regions 310 and 312. Spacer 315 improves electrical isolation between the gate the epitaxial regions. This isolation prevents electrical shorts or unintended capacitance between these regions, which could degrade the performance of the device.

Inter layer dielectric (ILD) 316 is deposited between metal layers of the SRAM. Silicon dioxide (SiO2), silicon nitride (SiN) or a low-k dielectric material may be used to form ILD 316. ILD 316 electrically isolates metal layers and prevents crosstalk or short circuits between adjacent interconnects, while still allowing vertical electrical connections through vias. ILD 316 ensures that signals in one metal layer do not interfere with signals in other layers. Additionally, ILD 316 provides structural stability by separating metal layers and maintaining their alignment during fabrication.

Similarly, channels 320 and 322 and epitaxial regions 324 and 326 are formed for transistor N2. Single diffusion block (SDB) 328 is formed to optimize the placement of the transistors and to isolate two active devices (e.g., transistors N1 and N2), and reduce parasitic effects in the SRAM.

After fabrication of NMOS transistors N1 and N2 in lower layer 302, bonding oxide 330 is deposited over lower layer 302, and upper layer 332 is transferred on top of bonding oxide 330 to serve as the substrate for transistors in upper layer 332.

In upper layer 332, PMOS transistors P1 and P2 are formed. Transistor P1 includes channels 340 and 342 and epitaxial (Epi) regions 344 and 346. Epitaxial regions 344 and 346 are formed as the source and drain regions of transistor P1. Metal gate 348 is formed across channels 340 and 342. In the illustrative embodiment, metal gate 348 is a high-k metal gate. Channels 350 and 352 and epitaxial regions 354 and 356 are formed for transistor P2. Metal gate 358 is formed across channels 350 and 352. Single diffusion block (SDB) 360 is formed to separate two active devices (e.g., P1 and P2).

As shown in cross-section view 300A, PMOS transistor P1 is vertically stacked above NMOS transistor N1, and PMOS transistor P2 is vertically stacked above NMOS transistor N2, thus forming a stacked SRAM structure. Transistors P1 and N1 form inverter 102 (shown in FIG. 1) and transistors P2 and P3 form inverter 104 (shown in FIG. 1).

FIG. 3B illustrates cross-section view 300B of the SRAM along X2 cut (as shown in FIG. 2) . In this cross-section view, the SRAM is shown at a point in fabrication after the FEOL process on the frontside of the device. As shown in cross-section view 300B, NMOS transistors N1 and N2 are fabricated in lower layer 302, and PMOS transistors P1 and P2 are fabricated in upper layer 332. Bonding oxide 330 is used to bond upper and lower layers 332 and 302.

Transistor N1 includes channels 306 and 308, gate 314 and epitaxial (Epi) regions 310 and 312. The other transistors (e.g., N2, P1 and P2) have similar structure. Single diffusion block (SDB) 328 is formed between the active devices in lower layer 302, and SDB 360 is formed between the active devices in upper layer 332. Inter layer dielectric (ILD) 316 is placed between different metal layers of the SRAM.

FIG. 3C illustrates cross-section view 300C of the SRAM along Y cut (as shown in FIG. 2) which runs transversely across X1 and X2 cuts. As shown in this view, lower layer 302 and upper layer 332 are bonded by bonding oxide 330. In this view, epitaxial regions 312 and 324 of respective transistors N1 and N2 and epitaxial regions 346 and 354 of respective transistors P1 and P2 are shown. Epitaxial regions 312 and 324 are separated from epitaxial regions 346 and 354 by bonding oxide 330. ILD 316 is placed between metal layers of the SRAM.

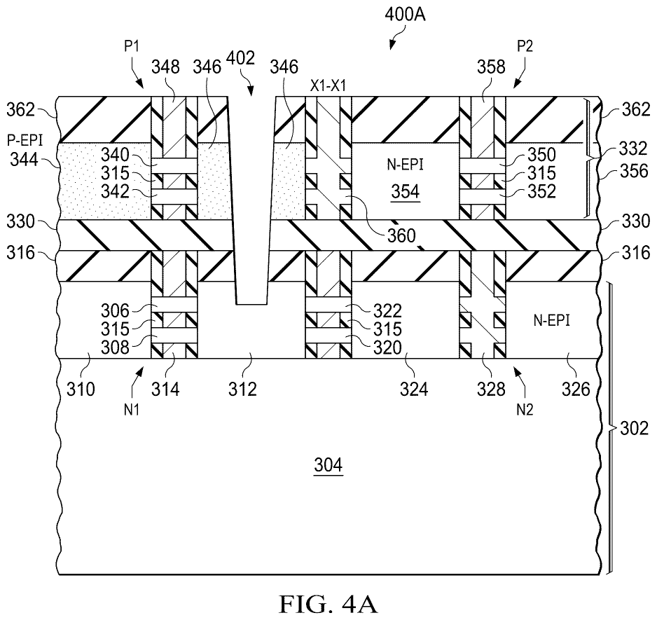

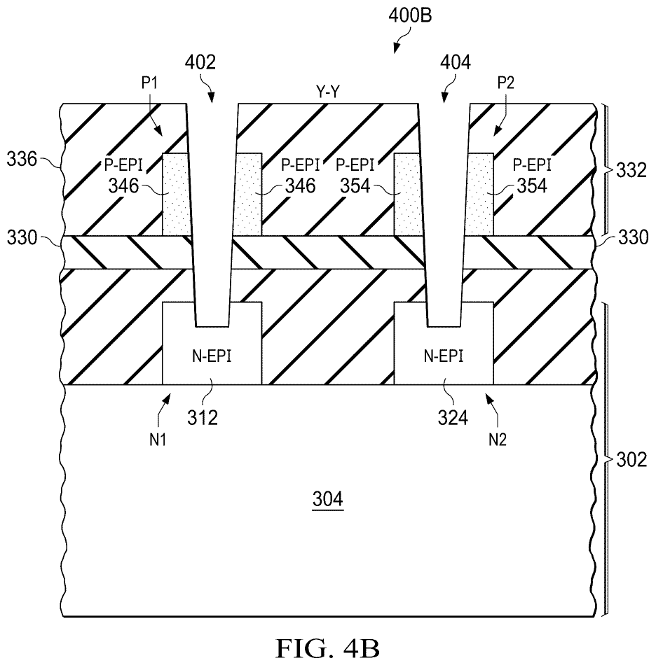

FIG. 4A illustrates cross-section view 400A of the SRAM along X1 cut (shown in FIG. 2). In this view, a single contact trench is shown. Contact trench 402 (also referred to as write word line contact) is formed by etching through epitaxial regions 360 and 312. Contact trench 402 extends from the upper layer into the lower layer.

FIG. 4B illustrates cross-section view 400B of the SRAM along Y cut (as shown in FIG. 2). In this view, two contact trenches are shown. Contact trench 402 is formed by etching through epitaxial regions 360 and 312 and contact trench 402 formed by etching through epitaxial regions 354 and 324.

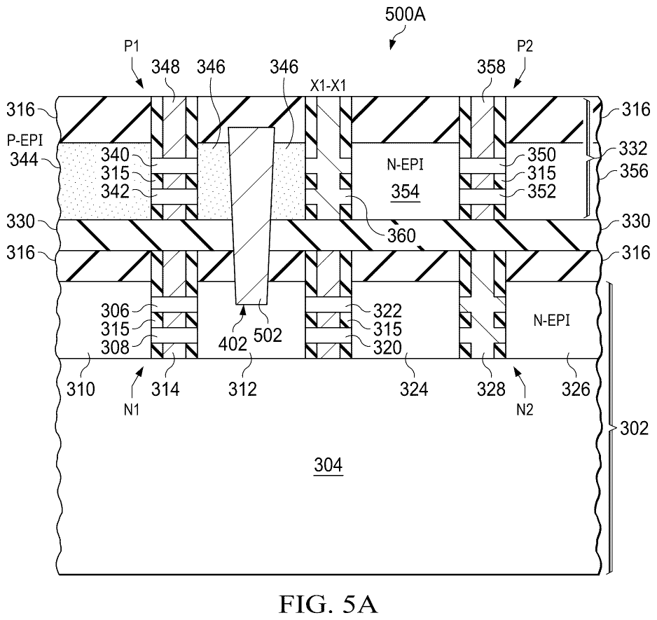

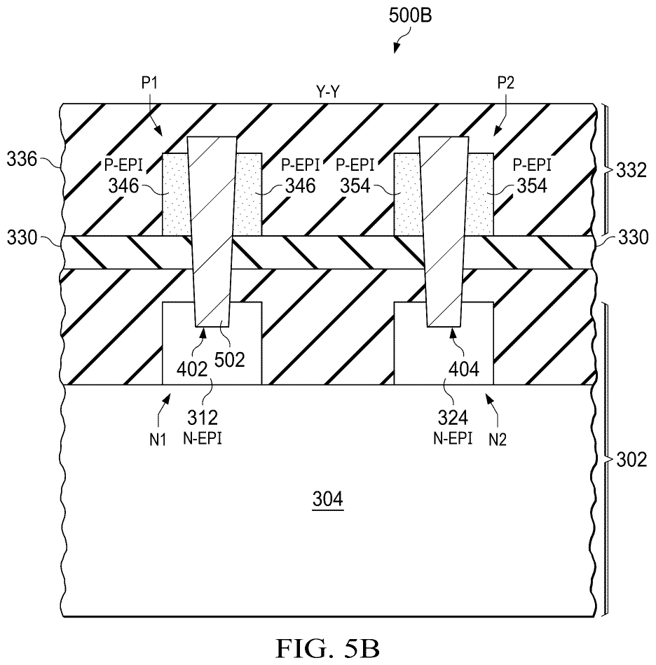

FIG. 5A shows cross-section view 500A of the SRAM along the X1 cut line (as shown in FIG. 2). In this view, contact trench 402 (as shown in FIGS. 4A and 4B) is filled with a metal 502 to create an electrical connection between epitaxial region 346 of PMOS transistor P1 and epitaxial region 312 of NMOS transistor N1. Contact trench 402 is a vertical channel that is filled with metal 502, allowing electrical continuity between the PMOS and NMOS transistors through their respective epitaxial regions. Once metal 502 is in place to complete the connection, the rest of the trench is filled with ILD 316 to electrically isolate this connection from other layers or structures in the chip.

FIG. 5B shows cross-section view 500B of the SRAM along the Y cut line (as indicated in FIG. 2). In this view, contact trenches 402 and 404 are shown filled with a metal. Contact trench 402 creates electrical connection between P1 and N1 and contact trench 404 creates electrical connection between P2 and N2.

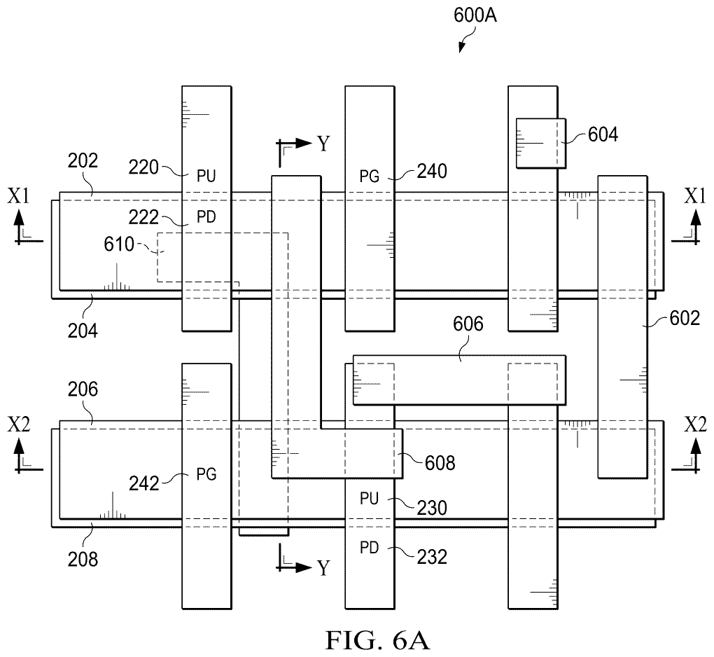

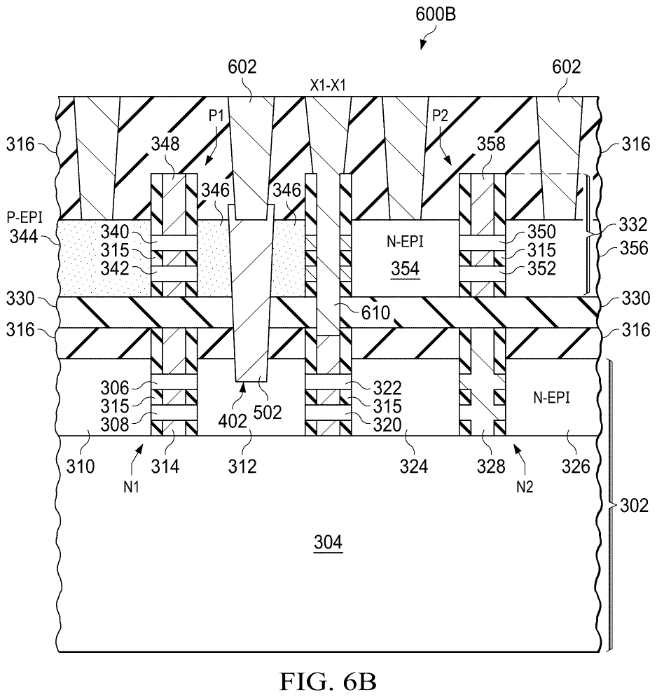

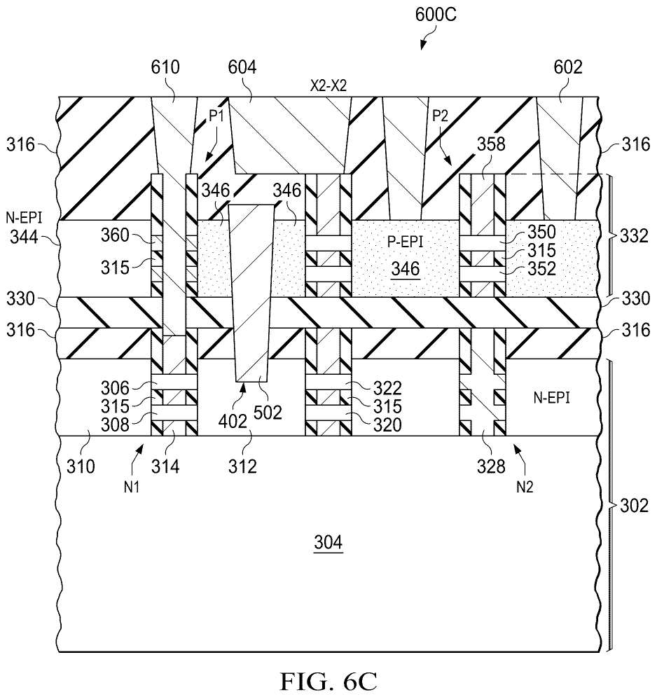

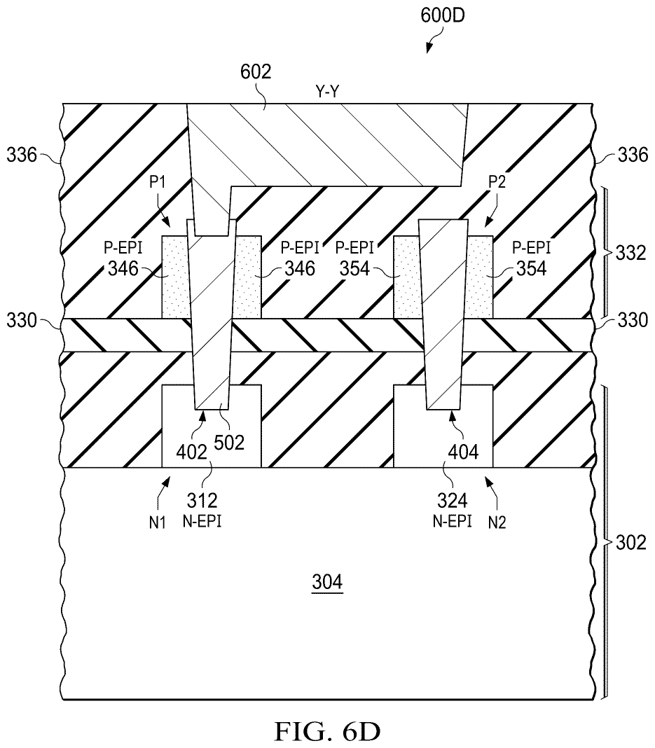

FIG. 6A shows top view 600A (layout) of the SRAM (e.g., SRAM 100, 200) at a point in fabrication after a middle of line (MOL) process on the frontside of the wafer. The MOL process is a step in fabrication that occurs between the front end of line (FEOL) and back end of line (BEOL) processes. The MOL process forms contacts that connect the transistor gates, sources, and drains from the FEOL to metal interconnect layers in the BEOL. The MOL process establishes initial contacts and close-range interconnects immediately above the active devices. It also enables SRAM cells to access essential components (e.g., linking a transistor's source/drain to the gate of another transistor) without the need for higher metal routing.

As shown in FIG. 6A, X1 cut runs laterally across active regions 202 and 204 which are formed in upper and lower layers, respectively, of the IC, and X2 cut runs laterally across active regions 206 and 208 which are formed in upper and lower layers, respectively, of the IC. Additionally, Y1 cut runs transversely across X1 and X2 cuts.

In the illustrative embodiment, contact 602 (CA) establishes a connection (e.g., an internal bridge) between source/drain of the transistors to metal layers. This connection enables signal flow within the transistor network. Contact 604 (CB) links the gate of transistor N3 (as shown in FIG. 1) to read word line (RWL) (as shown in FIG. 1), facilitating the read operation in the SRAM. Contact 606 (CB) forms a connection between the gate of transistor P3 (as shown in FIG. 1) and inverters 102 and 104 (shown in FIG. 1). This contact enables the necessary connectivity for the proper functioning of these inverters in the SRAM circuit. Frontside cross-connect 608 and backside cross-connect 610 are used to cross-connect inverters 102 and 104 (as shown in FIG. 1). These cross-connects facilitate connections on both the upper and lower surfaces of the layout.

FIGS. 6B, 6C and 6D show cross-section views of the SRAM (e.g., SRAM 100, 200) along respective X1, X2 and Y cut lines (as indicated in FIG. 6A) at a point in fabrication after the MOL process. As shown in FIGS. 6B and 6C, write word line (WWL) 610, contact 602 (CA) and contact 604 (CB) are formed. WWL 610 is connected to the gates of transistors PG1 and PG2 (as indicated in FIG. 1). During a write operation, WWL 610 is asserted (e.g., driven HIGH) to turn ON transistors PG1 and PG2. In FIG. 6D, contact 602 (CA) and contact 612 (LI) form front side cross-connect 608 (as indicated in FIG. 6A).

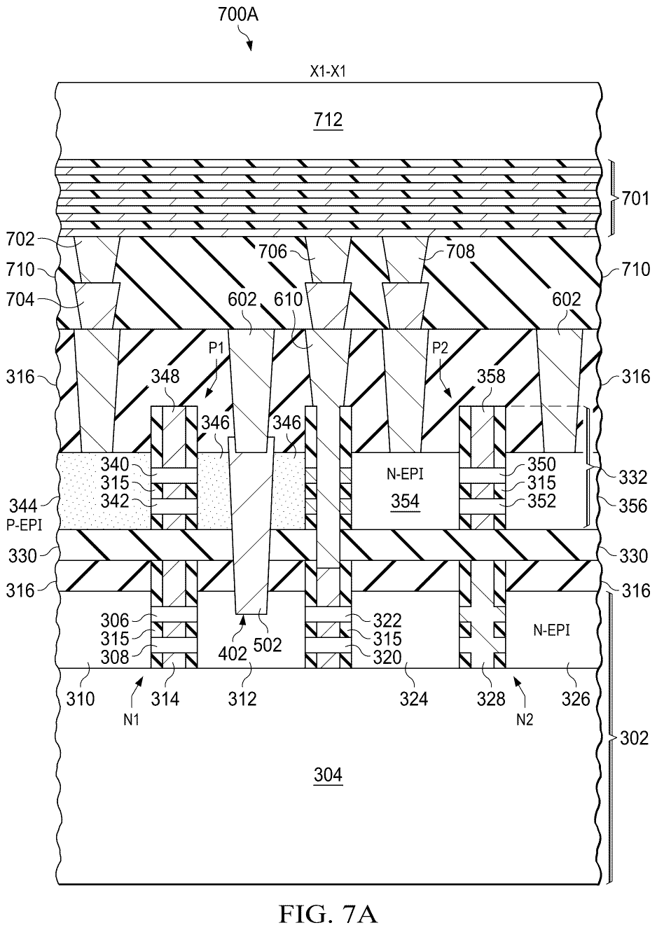

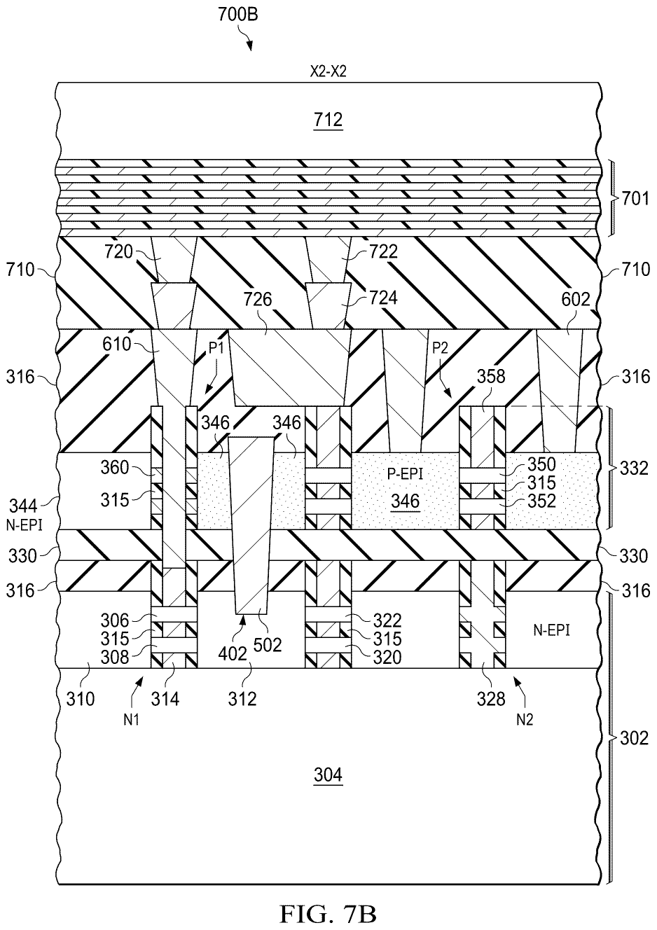

FIG. 7A shows cross-section view 700 of SRAM (e.g., SRAM 100, 200) along the X1 cut (shown in FIG. 6A) at a point in fabrication after a back end of line (BEOL) process to form BEOL 701. The BEOL process builds metal interconnect layers that connect different parts of the SRAM and other circuit blocks across the chip. The process involves creating multi-level metal layers, where the highest layers handle global interconnections across the entire chip.

As shown in FIG. 7A, power supply rail VDD 702 (also referred to as voltage rail), output node VO 704, write word line WWL 706 and read bit line RBLB 708 are formed in dielectric layer 710. VDD 702 distributes power across the SRAM and peripheral circuits (not shown in FIG. 7A). VDD 702 is connected to the source or drain terminals of the transistors via intermediate layers (e.g., CA contacts) formed in the MOL process. VO 704 routes output signal from the SRAM to other circuit components.

As shown in FIG. 7A, VO 704 is connected to contact (CA), thus connecting the output node to the source or drain of the transistor. In the BEOL process, write word line WWL 710 is electrically connected to another WWL which was previously formed in the MOL process. The placement of the WWLs across different fabrication layers (MOL and BEOL) enables efficient routing and connectivity. WWL 710 is routed in a higher metal layer to span larger distances across the chip. WWL 710 provides a global routing path for the write word line signal, enabling it to reach all the cells along a particular row in the SRAM array.

After BEOL 701 is formed, carrier wafer 712 is bonded to the BEOL. Carrier wafer 712 is typically made from materials (e.g., Si, glass, sapphire) that provide stability and support, particularly for thin or delicate device wafers.

FIG. 7B shows cross-section view 700B of SRAM (e.g., SRAM 100, 200) along the X2 cut (shown in FIG. 6A) at a point in fabrication after the BEOL process. As shown in this view, WWL 720 is connected to a WWL which is formed in the MOL process. Also shown in this view are VDD 722 which provides power to the transistors and VO 724 which routes outputs from the transistors. Contact 726 (CB) is connected to the gates of the transistors.

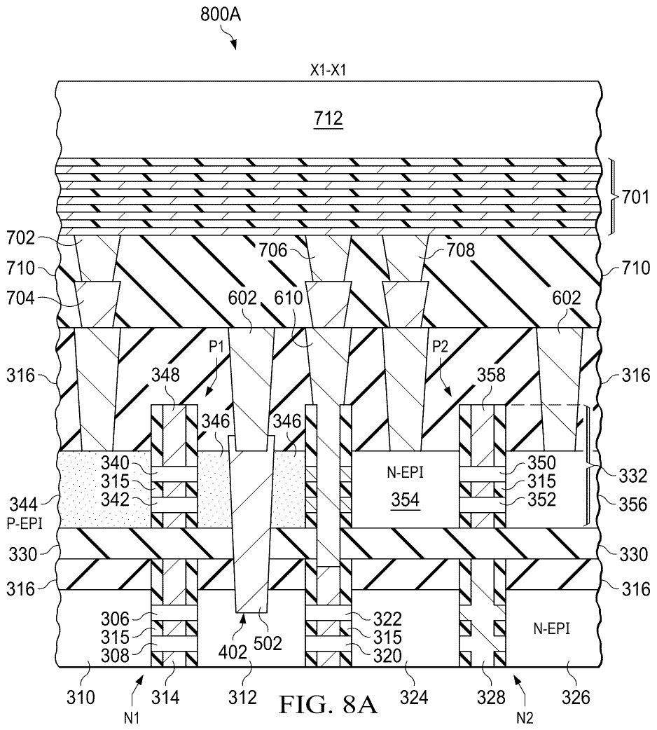

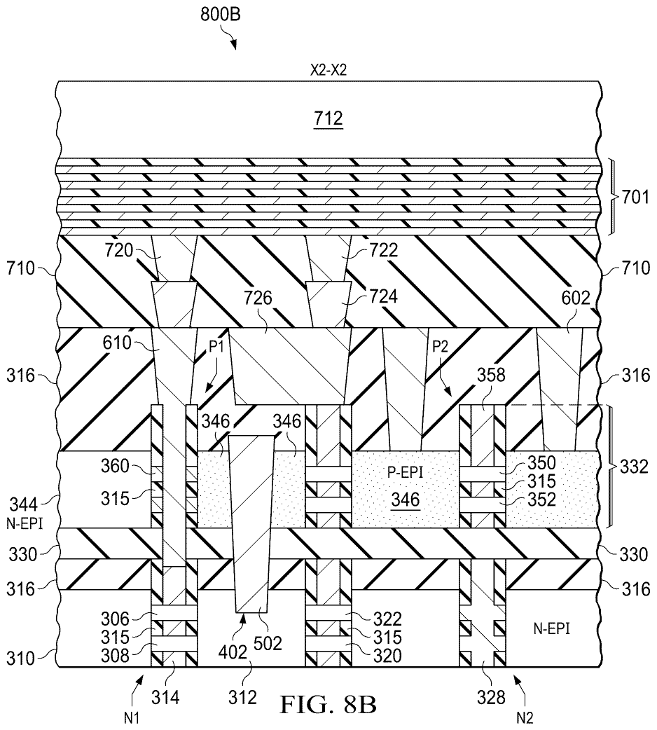

FIGS. 8A and 8B show respective cross section views 800A and 800B after removal of substrate 304. Once the frontside processing (FEOL, MOL and BEOL) is complete, the backside processing proceeds. The silicon wafer is flipped, exposing the bottom or backside of substrate 304. Substrate 304 may be completely removed (as shown in FIGS. 8A and 8B) to expose the buried layers. The removal process typically involves mechanical grinding followed by selective etching to achieve a precise, smooth backside surface.

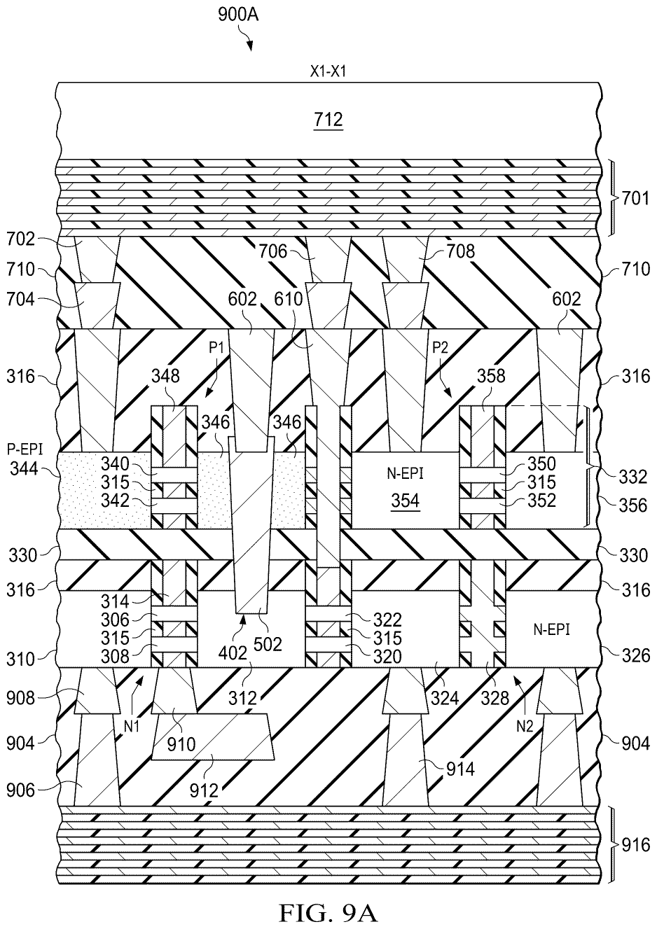

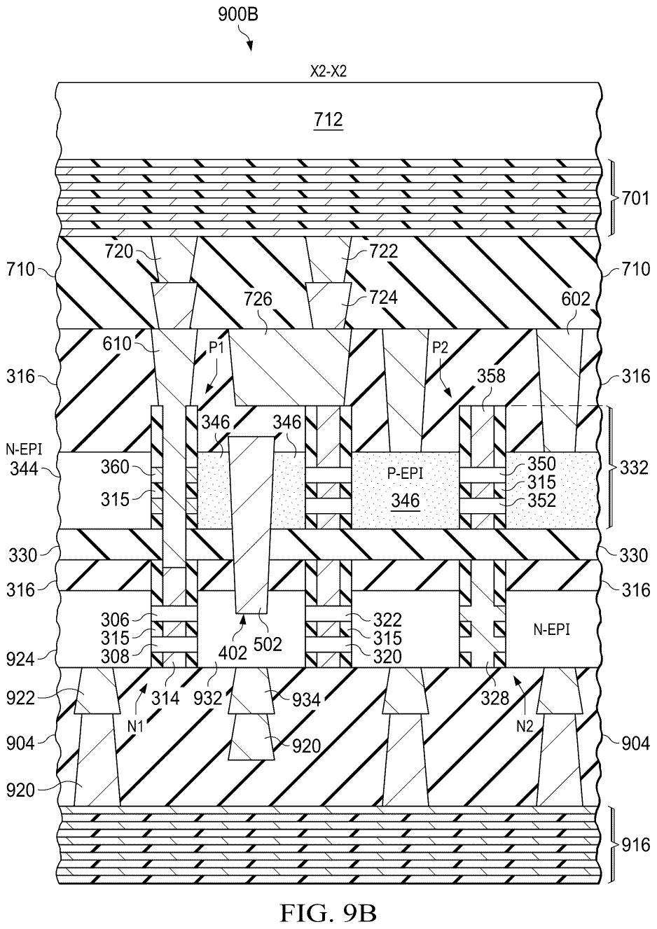

FIG. 9A shows cross-section views 900A of the SRAM (e.g., SRAM 100, 200) along the X1 cut (shown in FIG. 6A) after contacts are formed to establish backside connectivity and inter layer dielectric (ILD) is deposited on the backside.

As shown in FIG. 9A, ILD 904 is deposited on the backside to provide insulation between different metal layers and components. Contacts are formed through ILD 804 to establish backside connectivity (electrical connections) with the active elements on the frontside of the wafer. In this example, VSS 906 (also referred to as ground rail), BSCA 908, BSCB 910, BSLI 912 and BLB 914 are formed through ILD 904. VSS 906 provides a stable reference potential (e.g., ground). BSCA 908 connects between the active transistor regions (such as source/drain terminals) and VSS 906. BSCB 910 connects to BSLI 912 (backside local interconnect) which routes signals to other nodes or layers. BLB 914 (backside bit line) corresponds to the bit line (BL) (shown in FIG. 1), which is used for write access to the SRAM cell. Backside Power Down Node (BSPDN) 916 is formed to facilitate backside power delivery. In an example embodiment, copper, cobalt or tungsten can be used to form BSPDN 916.

FIG. 9B shows cross-section view 900B of the SRAM (e.g., SRAM 100, 200) along the X2 cut after contacts are formed to establish backside connectivity and inter layer dielectric (ILD) is deposited on the backside. In this view, BL 920 corresponds to the write bit line BL which is connected to pass gate transistor PG1 (as shown in FIG. 1). BL 920 carries a signal that represents either 0 or 1 stored in the SRAM. As shown in FIG. 9B, BL 920 is connected to epitaxial region 924 via contact 922. BLSI 930 establishes a connection which forms the cross-connect between drains 124/128 and gates 114/120 (as shown in FIG. 1). As shown in FIG. 9B, BLSI 930 is connected to epitaxial region 932 via BSCA 934.

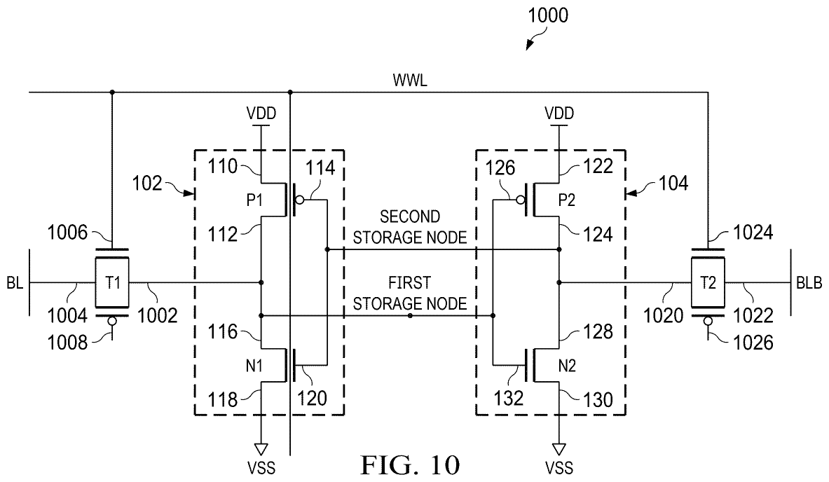

FIG. 10 illustrates a schematic of SRAM 1000 in accordance with another illustrative embodiment. In the illustrative embodiment, SRAM 1000 is implemented with two transfer gates, T1 and T2. T1 and T2 are switching devices which utilize complementary gate signals to achieve bidirectional conduction.

SRAM 1000 includes 2 cross-coupled inverters 102 and 104 that holds the data in a bistable flip-flop. Inverters 102 and 104 are implemented using Complementary Metal Oxide Semiconductor (CMOS) technology that includes both NMOS and PMOS transistors.

Inverter 102 includes PMOS transistor P1 and NMOS transistor N1. Transistor P1 has source 110 connected to voltage supply VDD (e.g., voltage rail) and has drain 112 and gate 114. Transistor N1 has drain 116 connected to drain 112 of P1 and has source 118 connected to reference potential VSS (e.g., ground) and has gate 120. Drains 112/116 are also referred to as the first storage node of SRAM 1000.

Inverter 104 includes PMOS transistor P2 and NMOS transistor N2. Transistor P2 has source 122 connected to voltage supply VDD and has drain 124 and gate 126. Transistor N2 has drain 128 connected to drain 124 of P2 and has source 130 connected to reference potential VSS (e.g., ground) and has gate 132.

Inverters 102 and 104 are cross-connected by connecting drains 112/116 to gates 126/132 and by connecting drains 124/128 to gates 114/120. The node at which drains 112/116 and gates 126/132 are interconnected is referred to as the first storage node. The node at which drains 124/128 and gates 114/120 are interconnected is referred to as the second storage node.

SRAM 1000 includes transfer gate T1 which has first terminal 1002 connected to drains 112/116, second terminal 1004 connected to bit line (BL), first gate 1006 connected to write word line (WWL) and second gate 1008 coupled to receive a signal that is complementary to the signal carried by WWL.

SRAM 1000 includes transfer gate T2 which has first terminal 1020 connected to drains 124/128, second terminal 1022 connected to bit line bar (BLB) (also referred to as complementary BL), first gate 1024 connected to WWL and second gate 1026 coupled to receive a signal that is complementary to the signal carried by WWL.

In the illustrative embodiment, T1 acts as a controlled switch that allows or blocks bidirectional current flow between BL and first storage node, and T2 acts are a controlled switch that allows or blocks bidirectional current flow between BLB and the second storage node. During a write operation, WWL is asserted (e.g., driven HIGH) and thus complementary WWL is driven LOW. As a result, a binary value from BL is stored at the first storage node and a binary value from BLB is stored at the second storage node. Thus, new data can be written into SRAM 1000. BL represents either binary value 0 or 1 and BLB represents the complementary binary value to BL.

During a read operation, WWL is driven LOW and thus complementary WWL is driven HIGH. As a result, a binary value from the first storage node is transferred to BL, and a binary value from the second storage node is transferred to BLB. Thus, data stored in SRAM 1000 can be read.

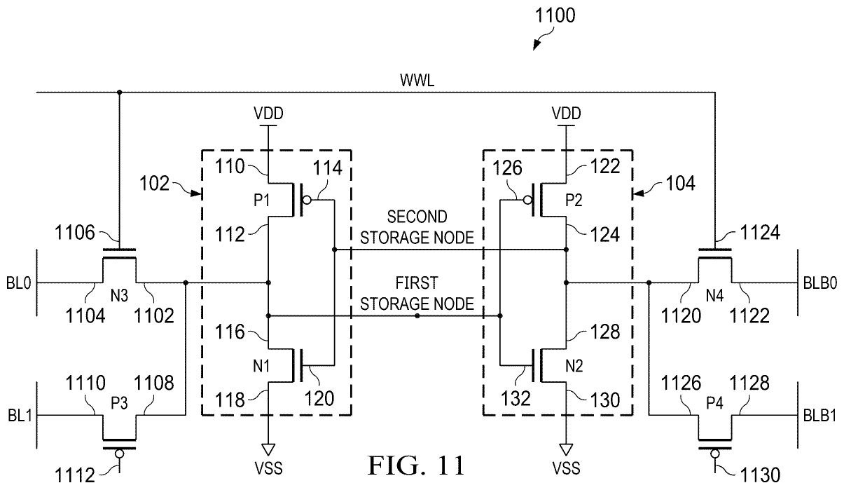

FIG. 11 illustrates a schematic of SRAM 1100 in accordance with another illustrative embodiment. SRAM 1100 is similar to SRAM 1000 (illustrated in FIG. 10) except first transfer gate T1 of SRAM 1000 is replaced by NMOS transistor N3 and PMOS transistor P3, and second transfer gate T2 of SRAM 1000 is replaced by NMOS transistor N4 and PMOS transistor P4.

NMOS transistor N3 has source 1102 connected to drains 112/116, drain 1104 coupled to bit line 0 (BL0) and gate 1106 connected to write word line (WWL). PMOS transistor P3 has drain 1108 connected to drains 112/116, source 1110 connected to bit line 1(BL1) and gate 1112 coupled to receive a signal that is complementary to the signal carried by WWL.

NMOS transistor N4 has source 1120 connected to drains 124/128, drain 1122 connected to bit line bar 0 (BLB0) and gate 1124 connected to write word line (WWL). PMOS transistor P4 has drain 1126 connected to drains 1124/1128, source 1128 connected to bit line complementary 1(BLB1) and gate 1130 connected to receive a signal that is complementary to the signal carried by WWL.

During a write operation, WWL is asserted (e.g., driven HIGH) and thus complementary WWL is driven LOW. As a result, a binary value from BL0 is stored at the first storage node and a binary value from BLB0 is stored at the second storage node. Thus, new data can be written into SRAM 1100. BL0 represents either binary value 0 or 1 and BLB0 represents the complementary binary value to BL.

During a read operation, WWL is driven LOW and thus complementary WWL is driven HIGH. As a result, a binary value from the first storage node is transferred to BL1, and a binary value from the second storage node is transferred to BLB1. Thus, data stored in SRAM 1100 can be read.

As used herein, “a number of,” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component.

Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A static random access memory (SRAM) circuit comprising:
a first storage node and a second storage node;
a first PMOS transistor having a source connected to a voltage supply, a drain connected to the first storage node and a gate connected to the second storage node;
a first NMOS transistor having a drain connected to the first storage node, a source connected to a reference potential and a gate connected to the second storage node;
a second PMOS transistor having a source connected to the voltage supply, a drain connected to the second storage node and a gate connected to the first storage node;
a second NMOS transistor having a drain connected to the second storage node, a source connected to the reference potential and a gate connected to the first storage node;
a first pass gate transistor having a first terminal connected to the first storage node, a second terminal connected to a write bit line and a gate connected to a write word line;
a second pass gate transistor having a first terminal connected to the second storage node, a second terminal connected to a complementary write bit line and a gate connected to the write word line;
a third NMOS transistor having a drain connected to a read bit line, a gate connected to a read word line and having a source; and
a third PMOS transistor having a source connected to the source of the source NMOS transistor, a gate connected to the first storage node and a drain connected to a reference potential.

2. The SRAM circuit of claim 1, wherein the first storage node stores a binary value that is complementary to the binary value stored by the second storage node.

3. The SRAM circuit of claim 1, wherein in a write operation, the write word line is driven high, causing the first pass gate transistor and the second pass gate transistor to turn ON.

4. The SRAM circuit of claim 1, wherein in a write operation, the write word line is driven high, causing the write bit line to be coupled to the first storage node and the complementary write bit line to be coupled to the second storage node.

5. The SRAM circuit of claim 1, wherein in a read operation, the read word line is driven high, causing the third NMOS transistor to turn ON.

6. The SRAM circuit of claim 1, wherein the first and second pass gate transistors are NMOS transistors.

7. The SRAM circuit of claim 1, wherein the third PMOS transistor is turned ON if the binary value stored at the first storage node is 0, and wherein the third PMOS transistor is turned OFF if the binary value stored at the first storage node is 1.

8. A static random access memory (SRAM) circuit comprising:
a first storage node and a second storage node;
a first and a second inverter cross-coupled at the first and second storage nodes;
a first pass gate transistor having a first terminal connected to the first storage node, a second terminal connected to a write bit line and a gate connected to a write word line;
a second pass gate transistor having a first terminal connected to the second storage node, a second terminal connected to a complementary write bit line and a gate connected to the write word line; and
a read circuit having a first terminal connected to a read bit line, a second terminal connected to the first storage node, a third terminal connected to a read word line and a fourth terminal connected to a reference potential.

9. The SRAM circuit of claim 8, wherein the first inverter comprises:
a first PMOS transistor having a source connected to a voltage supply, a drain connected to the first storage node and a gate connected to the second storage node; and
a first NMOS transistor having a drain connected to the first storage node, a source connected to the reference potential and a gate connected to the second storage node.

10. The SRAM circuit of claim 8, wherein the second inverter comprises:
a second PMOS transistor having a source connected to a voltage supply, a drain connected to the second storage node and a gate connected to the first storage node; and
a second NMOS transistor having a drain connected to the second storage node, a source connected to the reference potential and a gate connected to the first storage node.

11. The SRAM circuit of claim 8, wherein the read circuit comprises:
a third NMOS transistor having a drain connected to a read bit line, a gate connected to a read word line and having a source; and
a third PMOS transistor having a source connected to the source of the first NMOS transistor, a gate connected to the first storage node and a drain connected to the reference potential.

12. The SRAM circuit of claim 8, wherein the first storage node holds a binary value that is complementary to the binary value held by the second storage node.

13. The SRAM circuit of claim 8, wherein in a write operation, the write word line is driven high, causing the first pass gate transistor and the second pass gate transistor to turn ON.

14. The SRAM circuit of claim 8, wherein in a write operation, the write word line is driven high, causing the write bit line to be coupled to the first storage node and the complementary write bit line to be coupled to the second storage node.

15. The SRAM circuit of claim 8, wherein in a read operation, the read word line is driven high, causing the third NMOS transistor to turn ON.

16. A static random access memory (SRAM) integrated circuit, comprising:
an upper layer and a lower layer separated by a dielectric layer;
a plurality of PMOS transistors formed in the upper layer;
a voltage supply rail, a write word line, a read bit line and a read word line formed in the upper layer;
a plurality of NMOS transistors formed in the lower layer, wherein the plurality of PMOS transistors are vertically stacked over the plurality of NMOS transistors;
a ground rail, a write bit line and a complementary write bit line formed in the lower layer; and
a write word line contact extending from the upper layer into the lower layer to establish contact with a gate of one of the NMOS transistors in the lower layer.

17. The SRAM integrated circuit of claim 16, wherein the plurality of PMOS transistors include first, second and third PMOS transistors, and wherein the plurality of NMOS transistors include first, second, third, fourth and fifth NMOS transistors.

18. The SRAM integrated circuit of claim 17, wherein the first NMOS and PMOS transistors are connected to form a first inverter, and wherein the second NMOS and PMOS transistors are connected to form a second inverter.

19. The SRAM integrated circuit of claim 18, wherein the first and second inverters are cross-coupled via frontside and backside cross-connects.

20. The SRAM integrated circuit of claim 18, wherein the third and fourth NMOS transistors are pass gate transistors.

21. A static random access memory (SRAM) integrated circuit, comprising:
an upper layer and a lower layer separated by a dielectric layer;
first, second and third PMOS transistors formed in the upper layer;
a voltage supply rail, a write word line, a read bit line and a read word line formed in the upper layer;
first, second, third, fourth and a fifth NMOS transistors formed in the lower layer, wherein the plurality of PMOS transistors are vertically stacked over the plurality of NMOS transistors;
a ground rail, a write bit line and a complementary write bit line formed in the lower layer; and
a write word line contact extending from the upper layer into the lower layer to establish contact with a gate of the fifth NMOS transistor in the lower layer,
wherein the first NMOS and PMOS transistors are connected to form a first inverter, and wherein the second NMOS and PMOS transistors are connected to form a second inverter.

22. The SRAM integrated circuit of claim 21, wherein the first and second inverters are cross-coupled via frontside and backside cross-connects.

23. The SRAM integrated circuit of claim 21, further comprising a frontside interconnect electrically connected to the voltage supply rail, the write word line, the read bit line and the read word line.

24. The SRAM integrated circuit of claim 21, further comprising a backside interconnect electrically connected to the ground rail, the write bit line and the complementary write bit line.

25. The SRAM integrated circuit of claim 21, further comprising single diffusion block isolating active regions of the SRAM.
